(19) United States
(12) Patent Application Publication
(10) Pub. No.: US 2014/0248423 A1
(43) Pub. Date: Sep. 4, 2014

(54) METHOD OF ROLL TO ROLL PRINTING OF FINE LINES AND FEATURES WITH AN INVERSE PATTERNING PROCESS

(71) Applicants: Ed S. Ramakrishnan, Spring, TX (US); Robert J. Petcavich, The Woodlands, TX (US)

(72) Inventors: Ed S. Ramakrishnan, Spring, TX (US); Robert J. Petcavich, The Woodlands, TX (US)

(73) Assignee: Uni-Pixel Displays, Inc., The Woodlands, TX (US)

(21) Appl. No.: 13/784,717

(22) Filed: Mar. 4, 2013

(51) Int. Cl. H05K 3/12

(52) U.S. Cl. CPC H05K 3/1275
USPC 427/97.4

(57) ABSTRACT

A method of inverse image flexographic printing includes transferring an insulating ink to a plurality of inverse printing patterns disposed on a flexo master. The insulating ink is transferred from the plurality of inverse printing patterns to a substrate. The insulating ink disposed on the substrate is cured. A catalytic ink is deposited on a plurality of exposed portions of the substrate. The catalytic ink deposited on the substrate is electroless plated.

### BACKGROUND OF THE INVENTION

An electronic device with a touch screen allows a user to control the device by touch. The user may interact directly with the objects depicted on the display through touch or gestures. Touch screens are commonly found in consumer, commercial, and industrial devices including smartphones, tablets, laptop computers, desktop computers, monitors, gaming consoles, and televisions. A touch screen includes a touch sensor that includes a pattern of conductive lines disposed on a substrate.

Flexographic printing is a rotary relief printing process that transfers an image to a substrate. A flexographic printing process may be adapted for use in the fabrication of touch sensors. In addition, a flexographic printing process may be adapted for use in the fabrication of flexible and printed electronics (“FPE”).

### BRIEF SUMMARY OF THE INVENTION

According to one aspect of one or more embodiments of the present invention, a method of inverse image flexographic printing includes transferring an insulating ink to a plurality of inverse printing patterns disposed on a flexo master. The insulating ink is transferred from the plurality of inverse printing patterns to a substrate. The insulating ink disposed on the substrate is cured. A catalytic ink is deposited on a plurality of exposed portions of the substrate. The catalytic ink deposited on the substrate is electroless plated.

Other aspects of the present invention will be apparent from the following description and claims.

### BRIEF DESCRIPTION OF THE DRAWINGS

FIG. 1 shows a side view of a conventional flexographic printing system.

FIG. 2 shows a side view of a flexographic printing system.

FIG. 3 shows a top view of high-resolution conductive lines produced by the flexographic printing system of FIG. 2.

FIG. 4 shows a flexo master with inverse printing or embossing patterns in accordance with one or more embodiments of the present invention.

FIG. 5 shows a first printing stage of an inverse flexographic printing system in accordance with one or more embodiments of the present invention.

FIG. 6 shows a second printing stage of an inverse flexographic printing system in accordance with one or more embodiments of the present invention.

FIG. 7 shows a top view of high-resolution conductive lines in accordance with one or more embodiments of the present invention.

FIG. 8 shows a side view of high-resolution conductive lines in accordance with one or more embodiments of the present invention.

FIG. 9 shows a method of inverse flexographic printing in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

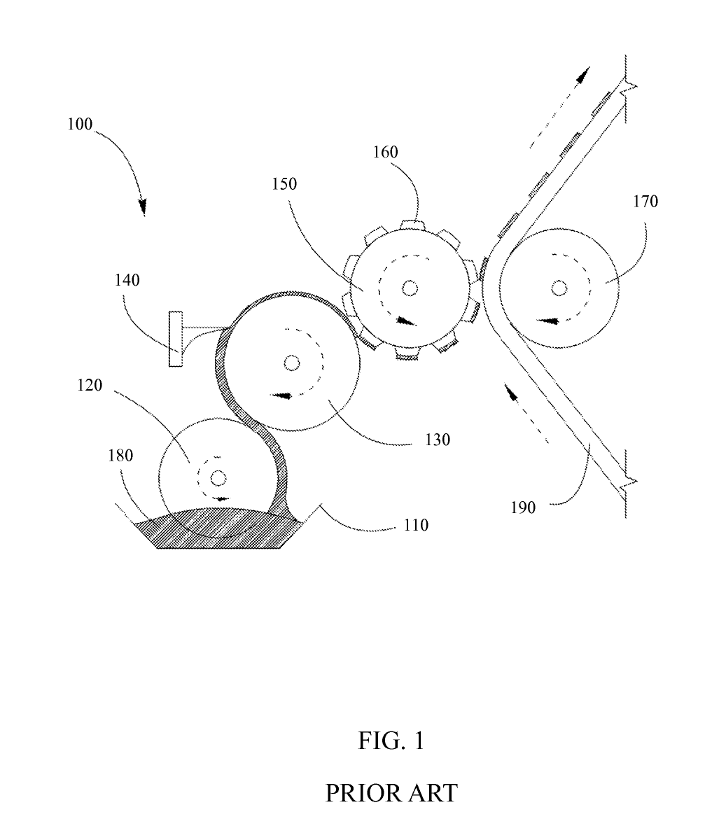

FIG. 1 shows a side view of a conventional flexographic printing system. A conventional flexographic printing system 100 includes an ink pan 110, an ink roll 120 (also referred to as a fountain roll), an anilox roll 130 (also referred to as a meter roll), a doctor blade 140, a printing plate cylinder 150, a flexo master 160, and an impression cylinder 170.

Ink roll 120 transfers ink 180 from ink pan 120 to anilox roll 130. Ink 180 may be any suitable combination of monomers, oligomers, polymers, metal elements, metal element complexes, or organometallics in a liquid state. Anilox roll 130 is typically constructed of a steel or aluminum core that may be coated by an industrial ceramic whose surface contains a plurality of very fine dimples, known as cells (not shown). Doctor blade 140 removes excess of ink 180 from anilox roll 130. Anilox roll 130 meters the amount of ink 180 transferred to printing plate cylinder 150 to a uniform thickness. Printing plate cylinder 150 may be generally made of metal and the surface may be plated with chromium, or the like, to provide increased abrasion resistance. Flexo master 160, also known as a flexographic printing plate, covers printing plate 150. Flexo master 160 may be composed of a rubber or photo-polymer. Flexo master 160 includes printing or embossing patterns that are used to print an image of the printing or embossing patterns on a substrate 190. Substrate 190 moves between the printing plate cylinder 150 and impression cylinder 170. Impression cylinder 170 applies pressure to printing plate cylinder 150, thereby transferring the image from the printing or embossing patterns of flexo master 160 onto substrate 190. The rotational speed of printing plate cylinder 150 is synchronized to match the speed at which substrate 190 moves through the flexographic printing system 100. The speed may vary between 20 feet per minute to 2600 feet per minute.

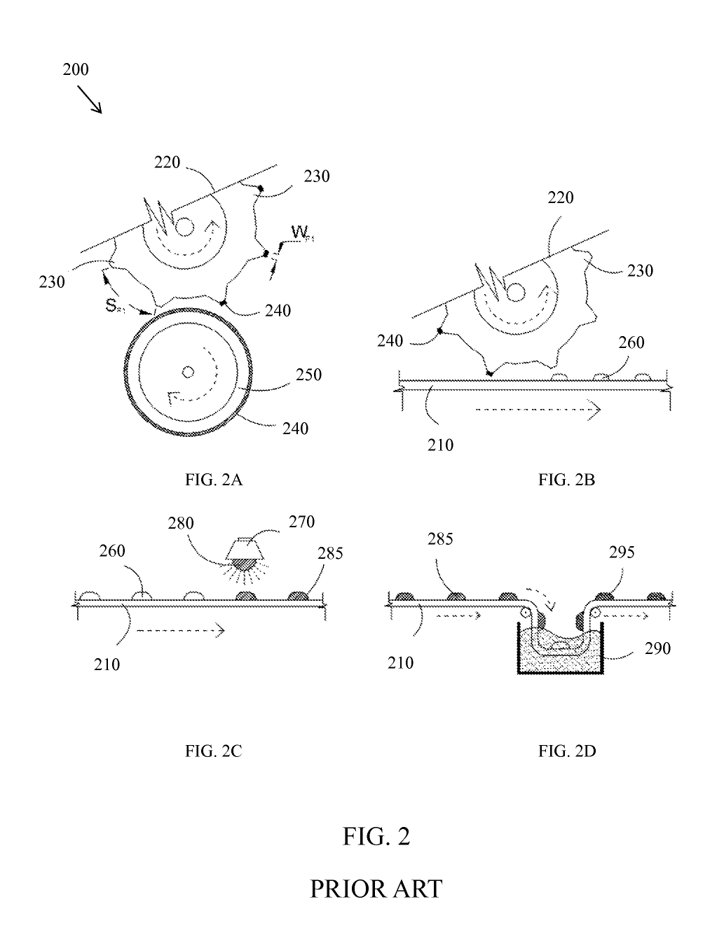

FIG. 2 shows a side view of a flexographic printing system in accordance with co-pending PCT International Patent Application Serial No. PCT/US12/61787, entitled “Method of Manufacturing a Capacitive Touch Sensor Circuit Using Flexographic Printing,” filed on Oct. 25, 2012, which claims priority to U.S. Provisional Patent Application Ser. No. 61/551,071, filed on Oct. 25, 2011, which is hereby incorporated by reference. Flexographic printing system 200 provides for the formation of high-resolution conductive lines on a substrate 210. With reference to FIG. 2A, a flexo master 220 comprises printing or embossing patterns 230 that receive ink 240 from anilox roll 250. Depending on the requirements of flexographic printing system 200, anilox roll 250 may be partially submersed in an ink pan (not shown), whereby a doctor blade (not shown) may remove excess ink 240 from the surface of anilox roll 250. The width, W_{F1}, of printing or embossing patterns 230 may vary from approximately 1 micron to approximately 20 microns, while spacing, S_{F1}, may vary from approximately 1 micron to approximately 5 millimeters. Ink 240 may include a combination of acrylics, urethane, polymers, and cross-linkable polymers. Ink 240 may be comprised of an acrylic monomer or polymer element with a concentration by weight of 10% to 99% obtained from commercial providers such as Sartomer, Radcure, or Double Bond, a photo-initiator or thermo-initiator element with a concentration by weight of 1% to 10% obtained from commercial providers such as Ciba Geigy, and a palladium acetate element with a concentration by weight of 0.1% to 15%.

Substrate 210 may be flexible or rigid and transparent or opaque. Substrate 210 may be comprised of plastic films such as polyesters, polyimides, polycarbonates, and polyacrylates. Flexible substrate 210 may be Dupont/Teijin Melinex 454 or Dupont/Teijin Melinex ST505, the latter being a heat stabilized film designed for processes that include heat treatment. For high-resolution applications, the surface of substrate 210 is required to be microscopically smooth with a thickness ranging from approximately 1 micron to approximately 1 millimeter. A corona treatment module (not shown) may be used to remove any small particles, oils, and grease from the surface of substrate 210 as necessary prior to printing ink 240. The corona treatment module may also be employed to increase the surface energy and obtain sufficient wetting and adhesion of substrate 210.

With reference to FIG. 2B, as flexo master 220 and anilox roll 250 rotate, ink 240 may be transferred from anilox roll 250 to the top surface of printing or embossing patterns 230, which subsequently transfer ink 240 to the surface of substrate 210, forming high-resolution printed lines 260.

With reference to FIG. 2C, as substrate 210 with high-resolution printed lines 260 passes through a UV curing module 270, a UV light source 280 initiates the polymerization of the acrylic element within the ink 240 composition and activates the plating catalyst, for example, palladium acetate. This curing and activation process may form plating precursor lines 285 on substrate 210. UV light source 280 can be a UVA or UVB ultraviolet light source, preferably an industrial grade UVA or UVB light source capable of curing the acrylic element in a very short period of time, approximately 0.01 seconds to approximately 2.0 seconds. UV light source 280 may exhibit a wavelength of approximately 280 nanometers to approximately 480 nanometers, with a target intensity ranging from approximately 0.1 mJ/cm² to approximately 1000 mJ/cm². Optionally, a second UV curing module (not shown) with similar wavelength and light intensity characteristics as UV curing module 270 may be used to ensure complete reduction of the plating catalyst before plating. In the case where inks composed of metal nano-particles are used, the curing binds the composite ink to the substrate.

With reference to FIG. 2D, substrate 210 with plating precursor lines 285 may be exposed to an electroless plating bath 290. A layer of conductive material is deposited on plating precursor lines 285 by submersing substrate 210 with plating precursor lines 285 into electroless plating bath 290. Electroless plating bath 290 may include copper, nickel, a combination thereof, or other conductive material in a liquid state at a temperature range between approximately 20 degrees Celsius and approximately 90 degrees Celsius. The deposition rate may be approximately 10 nanometers/minute and with a thickness in a range between approximately 0.001 microns to approximately 100 microns, depending on the speed of the web and the specifications of the application. After plating, high-resolution conductive lines 295 are formed on substrate 210 and pass through a cleaning stage by submersion in a cleaning tank (not shown) that contains water at room temperature. Following the cleaning stage, high-resolution conductive lines 295 may be dried by a drying module (not shown) through the application of air at a flow rate of approximately 20 feet/minute at room temperature.

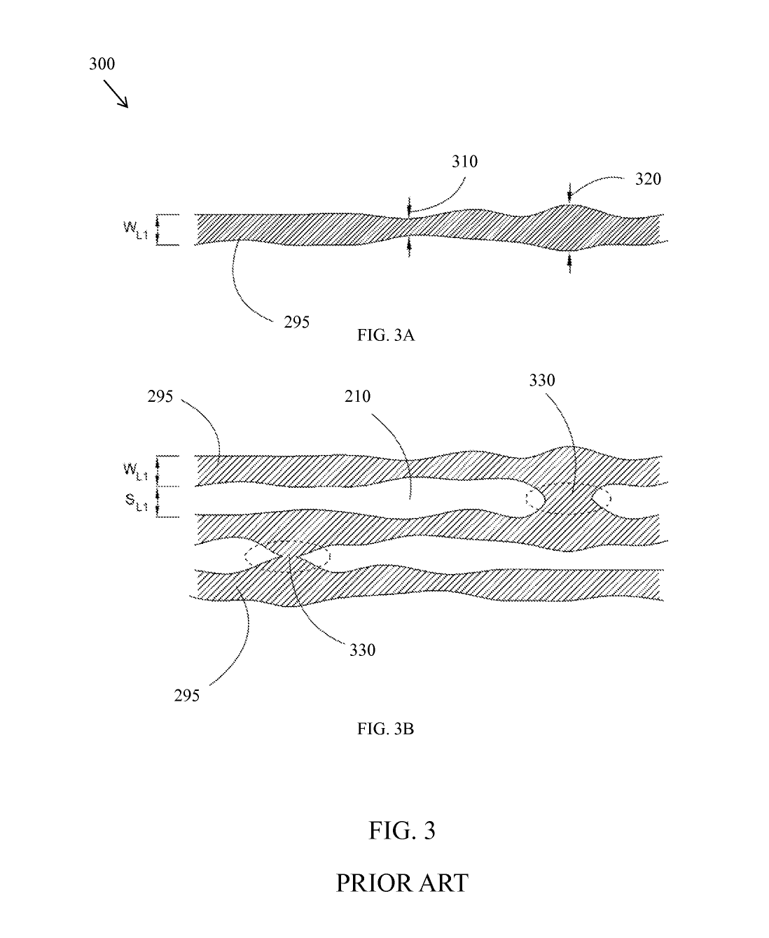

FIG. 3 shows a top view of high-resolution conductive lines produced by the flexographic printing system of FIG. 2. With reference to FIG. 3A, flexographic printing system 200 may allow for the formation of high-resolution conductive lines 295 on substrate 210, whereby the high-resolution conductive lines may exhibit a width, W_{L1}, of less than 10 microns. Because flexo master 220 is not completely stable during the printing of high-resolution conductive lines 295 and the flexibility of printing or embossing patterns 230, the width, W_{L1}, of high-resolution conductive lines 295 may vary, resulting in thin regions 310 or wide regions 320 along the longitude of high-resolution conductive lines 295 formed after electroless plating bath 290. For example, a 6 micron wide high-resolution conductive line 295 may have a width, W_{L1}, variation of approximately +/−1 micron to approximately +/−3 microns, which is not acceptable for many applications, including touch sensors. These width deviations increase as the target line width decreases, rendering the process unreliable.

With reference to FIG. 3B, when a spacing, S_{L1}, between high-resolution printed lines is less than 5 microns, line width, W_{L1}, variations may cause smearing or merging between high-resolution conductive lines 295 before they are completely cured by UV curing module 270. As a result, after electroless plating bath 290, high-resolution conductive lines 295 may exhibit contact areas 330 that may produce electrical shorts. In other cases, line width, W_{L1}, variations may form extremely thin regions 310, producing breaks or discontinuities (not shown) across the longitude of high-resolution conductive lines 295. Because of line width variations, high-resolution conductive lines 295 may result in electrical shorts if the spacing between lines is too small or open circuits when there are breaks in one or more lines.

Several limitations arise when printing high-resolution conductive lines smaller than 10 microns using the above-noted methods. There may be very high line width variations in a range between approximately 1 micron to approximately 3 microns that result in very thin or extra wide regions along the longitude of the high-resolution conductive lines. In addition, when the spacing between the high-resolution lines is less than 5 microns, the non-uniform line width may result in smearing or merging of two or more high-resolution conductive lines when the ink is printed on films or substrates. The smearing or merging may result in electrical shorts between high-resolution conductive lines or breaks across one or more high-resolution conductive lines resulting in open circuits.

In one or more embodiments of the present invention, a method of inverse flexographic printing allows for the formation of high-resolution conductive lines less than 10 micron in width with a line width variation in a range between approximately +/−0.1 micron to approximately 0.5 micron. In one or more embodiments of the present invention, a method of inverse flexographic printing allows for the formation of high-resolution conductive lines less than 10 micron in width with a line spacing of less than 5 microns.

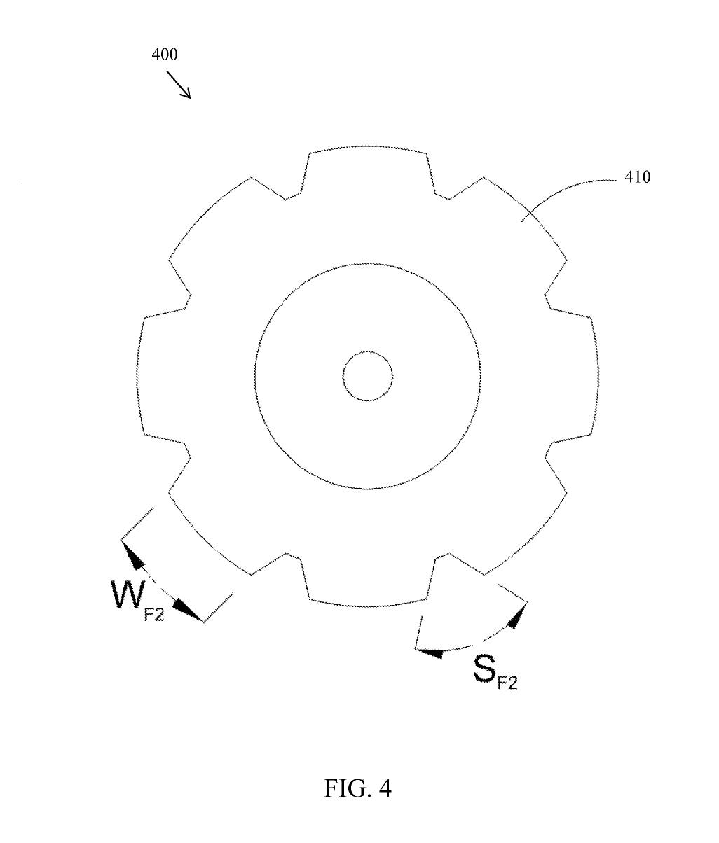

FIG. 4 shows a flexo master with inverse printing or embossing patterns in accordance with one or more embodiments of the present invention. Flexo master 400 includes inverse printing or embossing patterns 410. In one or more embodiments of the present invention, inverse printing or embossing patterns 410 produce an insulating image on substrate, leaving exposed portions on substrate for subsequent metallization. In one or more embodiments of the present invention, inverse printing or embossing patterns 410 produce an inverse image on substrate. In one or more embodiments of the present invention, flexo master 400 may be an inverse image of flexo master 220 of FIG. 2. In one or more embodiments of the present invention, flexo master 400 may include a mix of inverse printing or embossing patterns and non-inverse printing or embossing patterns. In one or more embodiments of the present invention, a width, W_{F2}, of inverse printing or embossing patterns 410 of flexo master 400 may correspond to spacing, S_{F1}, between printing or embossing patterns 230 of FIG. 2. In one or more embodiments of the present invention, a spacing, S_{F2}, between inverse printing or embossing patterns 410 of flexo master 400 may correspond to a width, W_{F1}, of printing or embossing patterns 230 of FIG. 2. In one or more embodiments of the present invention, width, W_{F2}, of inverse printing or embossing patterns 410 may vary in range between approximately 1 micron to approximately 5 microns and spacing, S_{F2}, may vary in a range between approximately 1 micron to approximately 20 microns.

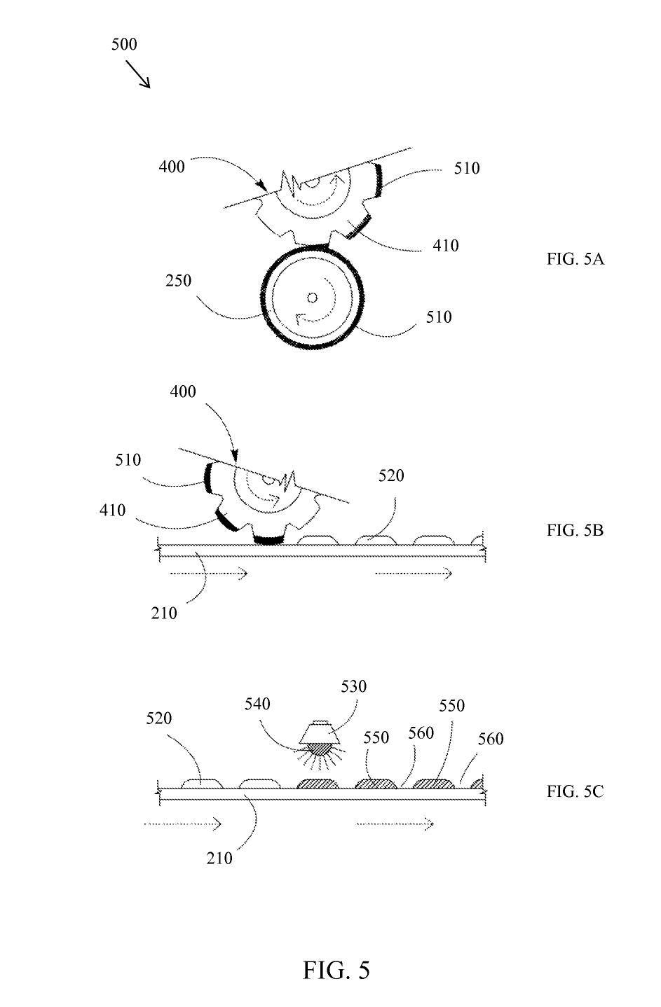

FIG. 5 shows a first printing stage of an inverse flexographic printing system in accordance with one or more embodiments of the present invention. In one or more embodiments of the present invention, first printing stage 500 may correspond to flexographic printing system 200 with modification. With reference to FIG. 5A, first printing stage 500 includes anilox roll 250 and flexo master 400. As anilox roll 250 and flexo master 400 rotate, an insulating ink 510 is transferred from anilox roll 250 to inverse printing or embossing patterns 410 of flexo master 400.

In one or more embodiments of the present invention, insulating ink 510 may be an oleo-phobic or hydrophobic ink that exhibits insulating properties and is transparent. In one or more embodiments of the present invention, transparent means the transmission of light with a transmittance rate of 90% or more. In one or more embodiments of the present invention, insulating ink 510 may be comprised of a combination of acrylics, urethane, polymers, and cross-linkable polymers. In one or more embodiments of the present invention, insulating ink 510 may be comprised of an acrylic monomer or polymer element with a concentration by weight of approximately 10% to approximately 99% that may be obtained from commercial providers such as Sartomer, Radcure, and Double bond and a photo-initiator or thermo-initiator element with a concentration by weight of approximately 1% to approximately 10% that may be obtained from commercial providers such as Ciba Geigy. In contrast to ink 240 of FIG. 2, insulating ink 510 may not require a plating catalyst, such as palladium acetate.

In one or more embodiments of the present invention, insulating ink 510 may include an oleo-phobic component with a concentration by weight of approximately 0.1% to approximately 10%. In one or more embodiments of the present invention, insulating ink 510 may include a hydrophobic component with a concentration by weight of approximately 0.1% to approximately 10%. In one or more embodiments of the present invention, the high optical transmittance of the printed/embossed film may remain on the final product after plating. If the insulating film has a low optical transmittance, solvents may remove it after plating. In one or more embodiments of the present invention, insulating ink 510 may be a sacrificial ink, i.e., water soluble or solvent soluble, that may be removed during or after plating. In one or more embodiments of the present invention, insulating ink 510 may be a water-soluble composition of polyvinyl alcohol, polyvinyl acetate, or other such materials that could be made into a viscous ink suitable for printing. In one or more embodiments of the present invention, insulating ink 510 may be a solvent-soluble composition.

In one or more embodiments of the present invention, insulating ink 510 may be a conductive metal ink such as gold, silver, copper, nickel, cobalt, iron, aluminum, or others which are available as nano-metals. In one or more embodiments of the present invention, when insulating ink 510 is a conductive metal ink, plating may not be required because the ink itself is conductive.

With reference to FIG. 5B, inverse printing or embossing patterns 410 of flexo master 400 transfer insulating ink 510 to substrate 210, forming inverse high-resolution printing lines 520. With reference to FIG. 5C, substrate 210 with inverse high-resolution printing lines 520 passes through a UV curing module 530. A UV light source 540 initiates the polymerization of the acrylic elements of insulating ink 510, with no plating catalyst activation required. In one or more embodiments of the present invention, the curing process may form lateral barriers 550 on substrate 210. UV light source 540 may be a UVA or UVB ultraviolet light source. In one or more embodiments of the present invention, UV light source 540 may be an industrial grade UVA or UVB light source capable of curing the acrylic element of insulating ink 510 in a very short period of time, approximately 0.01 seconds to approximately 2.0 seconds. UV light source 540 may exhibit a wavelength of approximately 280 nanometers to approximately 600 nanometers, with a target intensity ranging from approximately 0.1 mJ/cm² to approximately 1000 mJ/cm². In one or more embodiments of the present invention, a thermo-heating module (not shown) may apply heat within a temperature range between approximately 20 degrees Celsius to approximately 85 degrees Celsius to cure inverse high-resolution printed lines 520 and subsequent formation of lateral barriers 550. Because of the properties of insulating ink 510, lateral barriers 550 may exhibit hydrophobic properties. In one or more embodiments of the present invention, insulating ink 510 may be transparent. In one or more embodiments of the present invention, lateral barriers 550 bound valleys 560, or exposed portions, of substrate 210.

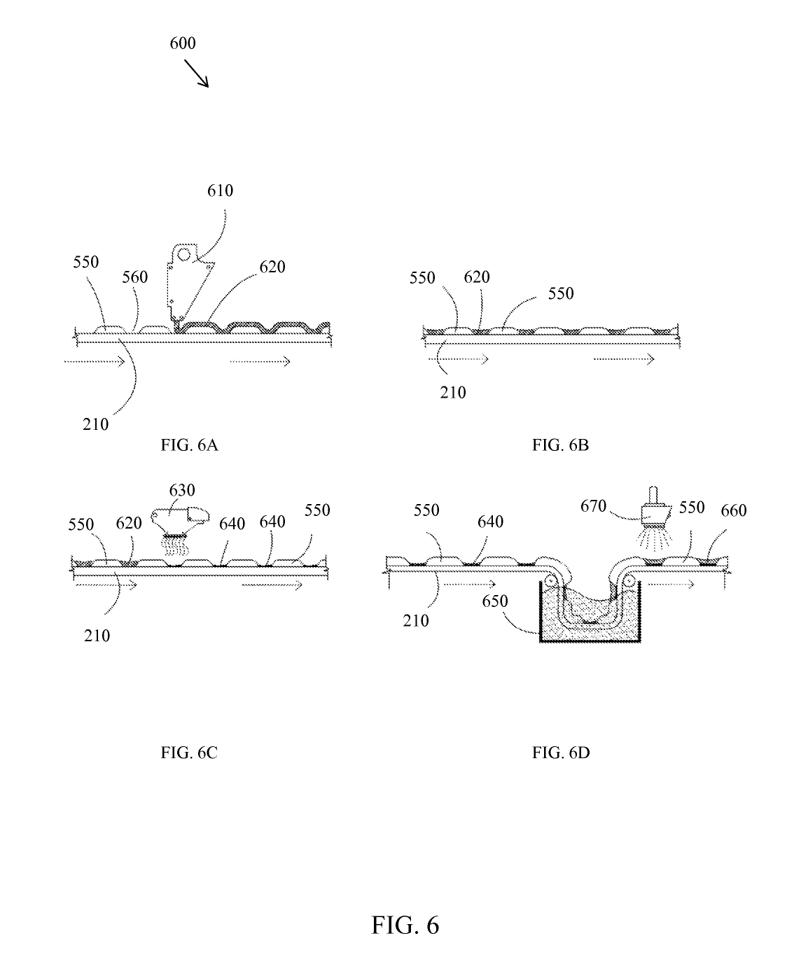

FIG. 6 shows a second printing stage of an inverse flexographic printing system in accordance with one or more embodiments of the present invention. With reference to FIG. 6A, a second printing stage 600 may include a slot-die coating module 610. Slot-die coating module 610 squeezes a catalytic ink 620 by pressure or gravity onto lateral barriers 550, valleys 560, and substrate 210. In one or more embodiments of the present invention, catalytic ink 620 forms a very thin conformal ink layer with a thickness of a few nanometers. In one or more embodiments of the present invention, catalytic ink 620 may be applied by spray coating, dip coating, painting, or brushing. One or ordinary skill in the art will recognize that other methods of depositing a catalytic ink may be used in accordance with one or more embodiments of the present invention.

In one or more embodiments of the present invention, catalytic ink 620 may include a combination of acrylics, urethane, polymers, and cross-linkable polymers. In one or more embodiments of the present invention, catalytic ink 620 may comprise an acrylic monomer or polymer element with a concentration by weight of approximately 10% to approximately 99% that may be obtained from commercial providers such as Sartomer, Radcure, and Double Bond, a photo-initiator or thermo-initiator element with a concentration by weight of approximately 1% to approximately 10% that may be obtained from commercial providers such as Ciba Geigy, and palladium acetate with a concentration by weight of approximately 0.1% to approximately 15%. In one or more embodiments of the present invention, because of the oleo-phobic or hydrophobic properties of insulating ink 510, catalytic ink 620 flows through valleys 560 and adheres to the exposed surfaces of substrate 210 and does not adhere to lateral barriers 550.

With reference to FIG. 6B, catalytic ink 620 settles in valleys 560 formed by lateral barriers 550 forming a transition zone. In one or more embodiments of the present invention, lateral barriers 550 may establish boundaries for catalytic ink 620. With reference to FIG. 6C, excess catalytic ink 620 may be removed. In one or more embodiments of the present invention, excess catalytic ink 620 may be removed by an air knife 630 applying air at a flow rate of approximately 20 feet/minute at room temperature. After cleaning, a very thin layer of catalytic ink 620 remains in valleys 520, forming plating seed layers 640 on substrate 210. Plating seed layers 640 are suitable for metallization by an electroless plating process.

With reference to FIG. 6D, plating seed layers 640 within valleys 560 may be exposed to an electroless plating bath 650. During electroless plating bath 650, a layer of conductive material may be built up on plating seed layers 640. In one or more embodiments of the present invention, plating seed layers 640 comprise a suitable amount of palladium acetate for plating. In one or more embodiments of the present invention, electroless plating bath 650 may include copper, nickel, a combination thereof, or other conductive material in a liquid state at a temperature range between approximately 20 degrees Celsius and approximately 90 degrees Celsius. In one or more embodiments of the present invention, the deposition rate may be in a range between approximately 0.01 microns/minute to approximately 1 micron/minute. In one or more embodiments of the present invention, the deposition rate may be greater than 1 micron/minute. In one or more embodiments of the present invention, electroless plating layer may have a thickness in a range between approximately 0.001 microns to approximately 100 microns, depending on the speed of the web and the specifications of the application. After electroless plating bath 650, high-resolution conductive lines 660 are formed on substrate 210 within valleys 560 formed by lateral barriers 550. In one or more embodiments of the present invention, high-resolution conductive lines 660 may pass through a cleaning module 670. In one or more embodiments of the present invention, cleaning module 670 may apply deionized water at room temperature to remove by-products and impurities formed after electroless plating bath 650. In one or more embodiments of the present invention, high-resolution conductive lines 660 may have a resistance in a range between approximately 0.0015 micro Ohms to approximately 500 Ohms, depending on the application.

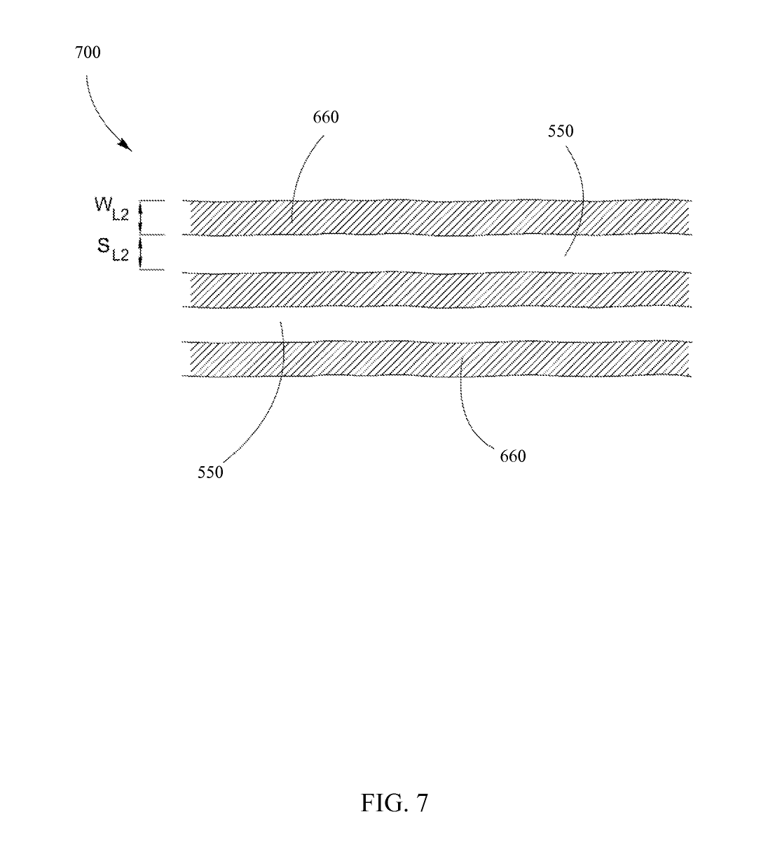

FIG. 7 shows a top view 700 of high-resolution conductive lines in accordance with one or more embodiments of the present invention. In one or more embodiments of the present invention, high-resolution conductive lines 660 are more uniform with respect to line width, W_{L2}, as compared to line width, W_{L1}, of FIG. 3. In one or more embodiments of the present invention, high-resolution conductive lines 660 have a line width that varies in a range between approximately +/−0.1 to approximately 0.3 microns, thereby eliminating thin regions 310 or wide regions 320 of FIG. 3. In one or more embodiments of the present invention, high-resolution conductive lines 660 are more uniform with respect to line spacing, S_{L2}, as compared to line spacing, S_{L1}, of FIG. 3. In one or more embodiments of the present invention, because high-resolution conductive lines 660 are more uniform, line spacings, S_{L2}, less than 5 microns can be achieved without smearing or formation of shorts or contact areas 330 of FIG. 3.

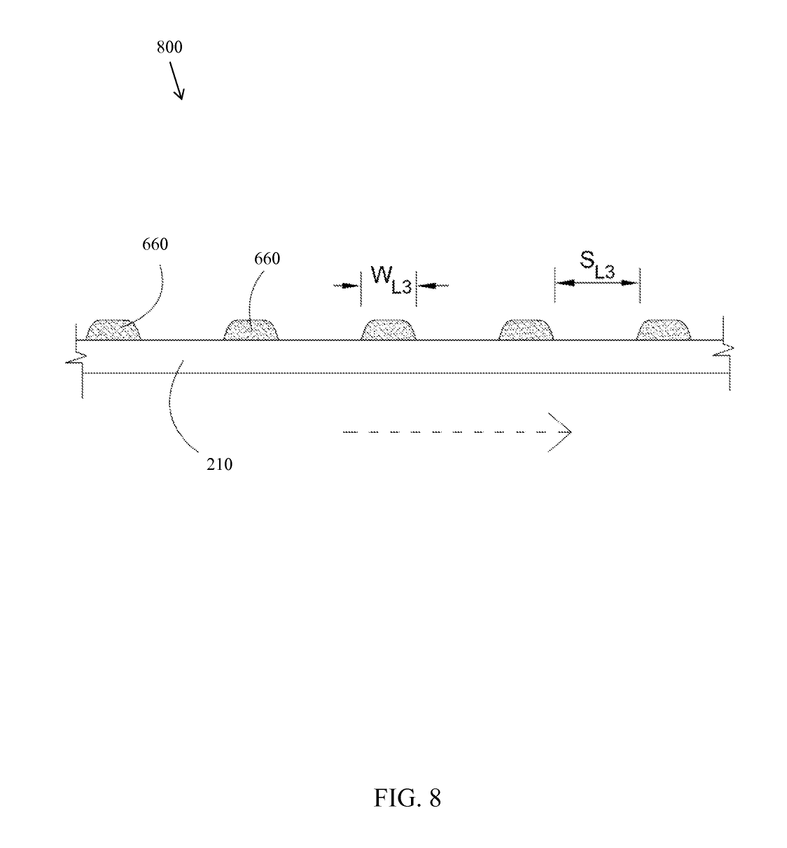

FIG. 8 shows a side view 800 of high-resolution conductive lines in accordance with one or more embodiments of the present invention. In one or more embodiments of the present invention, lateral barriers 550 may be removed from substrate 210 leaving high-resolution conductive lines 660 on substrate 210. In one or more embodiments of the present invention, lateral barriers 550 may be sacrificially removed from substrate 210 during or after electroless plating bath 650. In one or more embodiments of the present invention, as plating seed layers 640 enclosed in lateral barriers 550 passes through electroless plating bath 650, lateral barriers 550 may be gradually dissolved during the process of plating. Lateral barriers 550 may remain long enough to allow enough electroless plating of copper, nickel, a combination thereof, or other conductive material over plating seed layers 640. After electroless plating, lateral barriers 550 may be completely removed, leaving only high-resolution conductive lines 660 on substrate 210. In one or more embodiments of the present invention, insulating ink 510 is solvent soluble and a plating composition used in electroless plating bath 650 may include a solvent. In one or more embodiments of the present invention, a solvent can be applied over high-resolution conductive lines 660 and lateral barriers 550 to remove solvent soluble lateral barriers 550.

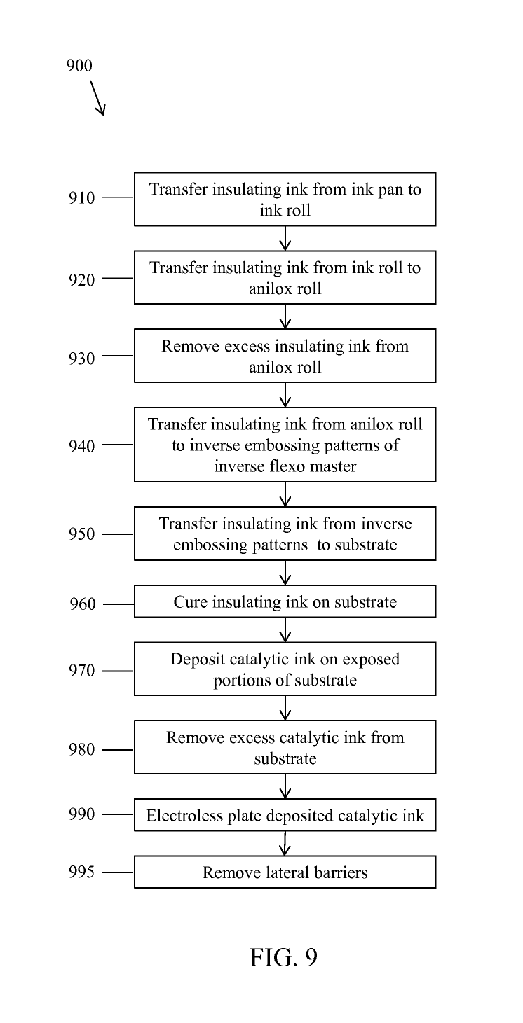

FIG. 9 shows a method of inverse image flexographic printing in accordance with one or more embodiments of the present invention. In step 910, an insulating ink may be transferred from an ink pan to an ink roll. In one or more embodiments of the present invention, the insulating ink may be an oleo-phobic ink. In one or more embodiments of the present invention, the insulating ink may be a hydrophobic ink. In one or more embodiments of the present invention, the insulating ink may be comprised of a combination of acrylics, urethane, polymers, and cross-linkable polymers. In one or more embodiments of the present invention, the insulating ink may be comprised of an acrylic monomer or polymer element with a concentration by weight of approximately 10% to approximately 99% that may be obtained from commercial providers such as Sartomer, Radcure, and Double bond and a photo-initiator or thermo-initiator element with a concentration by weight of approximately 1% to approximately 10% that may be obtained from commercial providers such as Ciba Geigy. In one or more embodiments of the present invention, the insulating ink is transparent. In one or more embodiments of the present invention, the insulating ink may include an oleo-phobic component with a concentration by weight of approximately 0.1% to approximately 10%. In one or more embodiments of the present invention, the insulating ink may include a hydrophobic component with a concentration by weight of approximately 0.1% to approximately 10%. In one or more embodiments of the present invention, the insulating ink may be a sacrificial ink, i.e., water soluble or solvent soluble, that may be removed during or after plating. In one or more embodiments of the present invention, the insulating ink may be a water soluble composition of polyvinyl alcohol, polyvinyl acetate, or other such materials that could be made into a viscous ink suitable for printing. In one or more embodiments of the present invention, the insulating ink may be a solvent soluble composition.

In step 920, the insulating ink may be transferred from the ink roll to an anilox roll. In step 930, excess insulating ink may be removed from the anilox roll. In step 940, the insulating ink may be transferred from the anilox roll to inverse printing or embossing patterns of a flexo master. In one or more embodiments of the present invention, the flexo master may be composed of rubber. In one or more embodiments of the present invention, the flexo master may be composed of a photo-polymer. In one or more embodiments of the present invention, the flexo master may be disposed on a plate cylinder.

In step 950, the insulating ink may be transferred from the inverse printing or embossing patterns to a substrate. In one or more embodiments of the present invention, the insulating ink produces an insulating image on substrate, leaving exposed portions on substrate for subsequent metallization. In one or more embodiments of the present invention, the substrate may be flexible. In one or more embodiments of the present invention, the substrate may be rigid. In one or more embodiments of the present invention the substrate may be transparent. In one or more embodiments of the present invention, the substrate may be opaque. In one or more embodiments of the present invention, the substrate may be polyethylene terephthalate (“PET”). In one or more embodiments of the present invention, the substrate may be polyethylene naphthalate (“PEN”). In one or more embodiments of the present invention, the substrate may be high-density polyethylene (“HDPE”). In one or more embodiments of the present invention, the substrate may be linear low-density polyethylene (“LLDPE”). In one or more embodiments of the present invention, the substrate may be bi-axially-oriented polypropylene (“BOPP”). In one or more embodiments of the present invention, the substrate may be a polyester substrate. In one or more embodiments of the present invention, the substrate may be a polypropylene substrate. In one or more embodiments of the present invention, the substrate may be a thin glass substrate. One of ordinary skill in the art will recognize that other substrates are within the scope of one or more embodiments of the present invention.

In step 960 the insulating ink disposed on the substrate may be cured. In one or more embodiments of the present invention, curing the insulated ink disposed on the substrate forms a plurality of lateral barriers. In one or more embodiments of the present invention, a UV light source may be used for curing. In one or more embodiments of the present invention, a UVA or UVB light source may be used for curing. In one or more embodiments of the present invention, a UV light source initiates the polymerization of the acrylic elements of the insulating ink, with no plating catalyst activation required.

In step 970, a catalytic ink may be deposited on a plurality of exposed portions of the substrate. In one or more embodiments of the present invention, the catalytic ink may include a combination of acrylics, urethane, polymers, and cross-linkable polymers. In one or more embodiments of the present invention, the catalytic ink may comprise an acrylic monomer or polymer element with a concentration by weight of approximately 10% to approximately 99% that may be obtained from commercial providers such as Sartomer, Radcure, and Double Bond, a photo-initiator or thermo-initiator element with a concentration by weight of approximately 1% to approximately 10% that may be obtained from commercial providers such as Ciba Geigy, and palladium acetate with a concentration by weight of approximately 0.1% to approximately 15%. In one or more embodiments of the present invention, the plurality of exposed portions of the substrate comprises an inverse image of the plurality of lateral barriers. In one or more embodiments of the present invention, the catalytic ink is suitable for metallization by electroless plating. In one or more embodiments of the present invention, the deposited catalytic ink may have a thickness of less than 10 nanometers. In one or more embodiments of the present invention, the deposited catalytic ink disposed on the exposed portions of the substrate comprise a plurality of plating seed layers suitable for metallization.

In step 980, excess catalytic ink may be removed from the substrate prior to electroless plating. In one or more embodiments of the present invention, excess catalytic ink may be removed from the substrate after electroless plating. In step 990, the deposited catalytic ink on the substrate may be electroless plated. In one or more embodiments of the present invention, the electroless plating metallizes the plurality of plating seed layers. In one or more embodiments of the present invention, the electroless plating may be electroless copper. In one or more embodiments of the present invention, the electroless plating may be electroless nickel. In one or more embodiments of the present invention, the electroless plating may be an electroless copper-nickel alloy. One of ordinary skill in the art will recognize that other metal allows may be used in accordance with one or more embodiments of the present invention. In one or more embodiments of the present invention, impurities may be removed from the plurality of plating seed layers prior to electroless plating. In one or more embodiments of the present invention, impurities may be removed from the plurality of plating seed layers after electroless plating.

In step 995, the plurality of lateral barriers may be removed. In one or more embodiments of the present invention, the plurality of lateral barriers may be removed during electroless plating, leaving high-resolution conductive lines on the substrate. In one or more embodiments of the present invention, the plurality of lateral barriers may be sacrificially removed from the substrate during or after the electroless plating. In one or more embodiments of the present invention, as plating seed layers pass through an electroless plating bath, the plurality of lateral barriers may be gradually dissolved during the process of plating. The plurality of lateral barriers may remain long enough to allow enough electroless plating of copper, nickel, a combination thereof, or other conductive material over the plurality of plating seed layers.

In one or more embodiments of the present invention, the plurality of lateral barriers may be removed after electroless plating, leaving high-resolution conductive lines on the substrate. In one or more embodiments of the present invention, the insulating ink may be solvent soluble and a plating composition used in the electroless plating bath may include a solvent. In one or more embodiments of the present invention, a solvent may be applied over high-resolution conductive lines and the plurality of lateral barriers to remove the solvent soluble plurality of lateral barriers.

Advantages of one or more embodiments of the present invention may include one or more of the following:

In one or more embodiments of the present invention, a method of inverse flexographic printing allows for the formation of high-resolution conductive lines less than 10 micron in width and a line width variation in a range between approximately +/−0.1 micron to 0.5 micron.

In one or more embodiments of the present invention, a method of inverse flexographic printing allows for the formation of high-resolution conductive lines with a line spacing of less than 5 microns.

In one or more embodiments of the present invention, a method of inverse flexographic printing allows for the formation of high-resolution conductive lines less than 10 micron in width and a line spacing of less than 5 microns without smearing or merging.

In one or more embodiments of the present invention, a method of inverse flexographic printing allows for the formation of high-resolution conductive lines less than 10 micron in width and a line spacing of less than 5 microns without breaks or discontinuities across the longitude of the high-resolution conductive lines.

In one or more embodiments of the present invention, a method of inverse flexographic printing allows for the fabrication of touch sensors that are more transparent because of the thin width and line spacing between high-resolution conductive lines.

In one or more embodiments of the present invention, a method of inverse flexographic printing allows for the fabrication of more precise touch sensors with a finer grid of high-resolution conductive lines.

In one or more embodiments of the present invention, a method of inverse flexographic printing simplifies manufacturing processes.

In one or more embodiments of the present invention, a method of inverse flexographic printing improves manufacturing efficiency.

In one or more embodiments of the present invention, a method of inverse flexographic printing reduces manufacturing waste.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of inverse image flexographic printing comprising:
transferring an insulating ink to a plurality of inverse printing patterns disposed on an flexo master;
transferring the insulating ink from the plurality of inverse printing patterns to a substrate;
curing the insulating ink disposed on the substrate;
depositing a catalytic ink on a plurality of exposed portions of the substrate; and
electroless plating the deposited catalytic ink on the substrate.

2. The method of claim 1, wherein the cured insulating ink disposed on the substrate comprise a plurality of lateral barriers on the substrate.

3. The method of claim 2, wherein the plurality of exposed portions of the substrate comprise an inverse image of the plurality of lateral barriers.

4. The method of claim 1, wherein the deposited catalytic ink disposed on the plurality of exposed portions of the substrate comprise a plurality of plating seed layers.

5. The method of claim 4, wherein the electroless plated substrate comprises electroless metallization of the plurality of plating seed layers.

6. The method of claim 5, wherein the metallized plurality of plating seed layers comprise a plurality of conductors.

7. The method of claim 6, wherein the plurality of conductors are transparent.

8. The method of claim 6, wherein the plurality of conductors have a width of less than 10 microns.

9. The method of claim 6, wherein the plurality of conductors have a width variation of less than 1 micron.

10. The method of claim 6, wherein the plurality of conductors have a spacing of less than 5 microns.

11. The method of claim 1, wherein the insulating ink is an oleo-phobic ink.

12. The method of claim 1, wherein the insulating ink is a hydrophobic ink.

13. The method of claim 1, wherein the deposited catalytic ink has a thickness of less than 10 nanometers.

14. The method of claim 1, wherein the deposited catalytic ink is suitable for electroless plating.

15. The method of claim 1, further comprising:
transferring ink from an ink pan to an ink roll;
transferring ink from the ink roll to an anilox roll; and
removing excess ink from the anilox roll.

16. The method of claim 1, further comprising:
removing excess catalytic ink from the substrate prior to electroless plating.

17. The method of claim 4, further comprising:
removing impurities from the plurality of plating seed layers after electroless plating.

18. The method of claim 2, further comprising:
removing the plurality of lateral barriers during electroless plating.

19. The method of claim 2, further comprising:
removing the plurality of lateral barriers after electroless plating.

20. The method of claim 1, wherein the substrate is polyethylene terephthalate.
